(19) United States
(12) Patent Application Publication
(10) Pub. No.: US 2011/0240115 A1
(43) Pub. Date: Oct. 6, 2011

(54) DOPED BUFFER LAYER

(76) Inventors: Benyamin Buller, (US); Dale Roberts, Temperance, MI (US); Rui Shao, (US)

(21) Appl. No.: 13/051,398

(22) Filed: Mar. 18, 2011

Related U.S. Application Data
(60) Provisional application No. 61/319,254, filed on Mar. 30, 2010.

(51) Int. Cl. H01L 31/0224; H01L 31/18; C23C 14/34; C23C 4/04; B22F 7/04; B32B 37/02; B05D 5/12

(52) U.S. Cl. 136/256; 438/98; 204/298.13; 427/452; 419/8; 156/60; 427/74; 257/E31.126

(57) ABSTRACT

A solar cell with a doped buffer layer includes silicon and tin.

### CROSS-REFERENCE TO RELATED APPLICATIONS

This application claims priority to U.S. Provisional Application Ser. No. 61/319,254, which was filed on Mar. 30, 2010, and is herein incorporated by reference in its entirety.

### TECHNICAL FIELD

This invention relates to a solar cell with a doped buffer layer.

### BACKGROUND

Photovoltaic devices can use transparent thin films that are also conductors of electrical charge. The conductive thin films can include transparent conductive layers that contain one or more transparent conductive oxide (TCO) layers. Past photovoltaic devices can be inefficient at converting solar power into electrical power.

### DESCRIPTION OF DRAWINGS

FIG. 1 is a schematic of a photovoltaic device having a transparent conductive oxide layer, multiple semiconductor layers, and a metal back contact.

FIG. 2 is a schematic of a photovoltaic device having transparent conductive oxide layers, an oxide buffer layer, multiple semiconductor layers, and a metal back contact.

FIG. 3 is a schematic showing a thermal spray process of making a doped sputter target.

FIG. 4 is a process flow chart of making a doped sputter target.

FIG. 5 is a schematic of a sputter target.

FIG. 6 is a schematic showing the reactive sputtering deposition process of the oxide buffer layer.

### DETAILED DESCRIPTION

Photovoltaic devices can use transparent thin films that are also conductors of electrical charge. The conductive thin films can include transparent conductive layers that contain one or more transparent conductive oxide layers. An oxide buffer layer can be deposited on top of TCO layers to improve the photovoltaic device performance when the buffer layer has the proper transparency, thickness, and conductivity. The buffer layer can be used to decrease the likelihood of irregularities occurring during the following process. However, a problem with the oxide buffer layer is that it may become too conductive, either as deposited or after post deposition processing. Doping with small amounts of dopant can keep the conductivity low under a range of post deposition processing conditions. The doped oxide buffer layer can be reactively sputter deposited from rotary targets in the presence of oxygen in a sputter chamber.

A photovoltaic device can include a substrate, a barrier layer adjacent to the substrate, a transparent conductive oxide layer adjacent to the barrier layer, and a buffer layer adjacent to the transparent conductive oxide layer. The buffer layer can include a silicon-doped tin oxide. The weight percentage of silicon to tin in the buffer layer can be between about 0.1% and about 20%, between about 0.5% and about 10%, or between about 0.1% and about 2%, or any other suitable percentage. The transparent conductive oxide layer can include cadmium oxide. The transparent conductive oxide layer can include cadmium tin oxide. The substrate comprises glass. The device can include a semiconductor bi-layer adjacent to the transparent conductive oxide layer. The semiconductor bi-layer can include a semiconductor absorber layer and a semiconductor window layer. The semiconductor absorber layer can include cadmium telluride. The semiconductor window layer can include cadmium sulfide. The barrier layer can include silicon oxide. The thicknesses of the buffer layer can be in the range of about 500 angstrom to about 5000 angstrom. The thicknesses of the buffer layer can be in the range of about 1000 angstrom to about 2500 angstrom.

The buffer layer can be deposited by sputtering a sputter target. The sputtering can include reactive sputtering. The sputter target can include tin and silicon. The sputter target can have a silicon weight percentage ranging from about 0.1% to about 20%, about 0.5% to about 10%, or about 0.1% to about 2.0%, or any other suitable percentage. The sputtering can include reactive sputtering from a rotary sputter target. The target can include tin and silicon. The sputtering can occur in the presence of oxygen in a sputter chamber.

A method of manufacturing a photovoltaic device can include depositing a barrier layer adjacent to a substrate, depositing a transparent conductive oxide layer adjacent to the barrier layer, and depositing a buffer layer adjacent to the transparent conductive oxide layer. The buffer layer can include silicon-doped tin oxide. The method can include depositing a semiconductor bi-layer adjacent to the buffer layer, wherein the semiconductor bi-layer comprises a semiconductor absorber layer and a semiconductor window layer.

Depositing the buffer layer can include sputtering a sputter target. Sputtering can include reactive sputtering. The sputter target can include tin and silicon. The sputter target can have a silicon weight percentage ranging from about 0.1% to about 20%, about 0.5% to about 10%, about 0.1% to about 2%, or any other suitable percentage. The sputtering can include reactive sputtering from a rotary target. The target can include tin and silicon. The sputtering can occur in the presence of oxygen in a sputter chamber. The sputter target can be formed by any suitable method. The sputter target can be formed by thermal spray forming. The sputter target can be formed by plasma spray forming. The sputter target can be formed by powder metallurgy. The powder metallurgy can include a hot press process. The powder metallurgy can include an isostatic process. The sputter target can be formed by flow forming.

The transparent conductive oxide layer can include cadmium oxide. The transparent conductive oxide layer can include cadmium tin oxide. The substrate can include glass. The semiconductor absorber layer can include cadmium telluride. The semiconductor window layer can include cadmium sulfide. The barrier layer can include silicon oxide. Depositing the transparent conductive oxide layer can include reactive sputtering from a doped target. The method can include an annealing step to anneal the transparent conductive oxide. The thicknesses of the buffer layer can be in the range of about 500 angstrom to about 5000 angstrom. The thicknesses of the buffer layer can be in the range of about 1000 angstrom to about 2500 angstrom.

A sputter target, including a sputter target used to form the buffer layer described above, can include a sputter material containing silicon and tin and a backing tube. The sputter material is connected to the backing tube to form a sputter target. The sputter target can include a silicon weight percentage of about 0.1% to about 20%, about 0.5% to about 10%, about 0.1% to about 2%, or any other suitable percentage. The sputter target can include a bonding layer bonding the sputter material and the backing tube. The backing tube can include stainless steel. The sputter target can be configured to use in reactive sputtering process.

A method of manufacturing a rotary sputter target configured for use in manufacture of photovoltaic device can include forming a sputter material that includes tin and silicon and attaching the sputter material to a backing tube. The step of forming the sputter target comprises a thermal spray forming process. The step of forming the sputter target can include a plasma spray forming process. The step of forming the sputter target can include a powder metallurgy process. The powder metallurgy can include hot press process. The powder metallurgy can include an isostatic process. The step of forming the sputter target can include a flow forming process. The sputter target can include a silicon weight percentage ranging from about 0.1% to about 20%, about 0.5% to about 10%, about 0.1% to about 2%, or any other suitable percentage. The step of attaching the sputter material to the backing tube can include bonding the sputtering material to the backing tube with a bonding layer. The backing tube can include stainless steel. The sputter target can be configured to use in reactive sputtering process.

A photovoltaic device can include a transparent conductive oxide layer adjacent to a substrate and layers of semiconductor material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current, which combined with the resulting voltage from the electric field, creates power. The result is the conversion of photon energy into electric power.

To preserve and enhance device performance, numerous layers can be positioned above the substrate in addition to the semiconductor window and absorber layers. Photovoltaic devices can be formed on optically transparent substrates, such as glass. Because glass is not conductive, a TCO layer is typically deposited between the substrate and the semiconductor bi-layer. Transparent conductive oxides function well in this capacity, as they exhibit high optical transmission and low electrical sheet resistance.

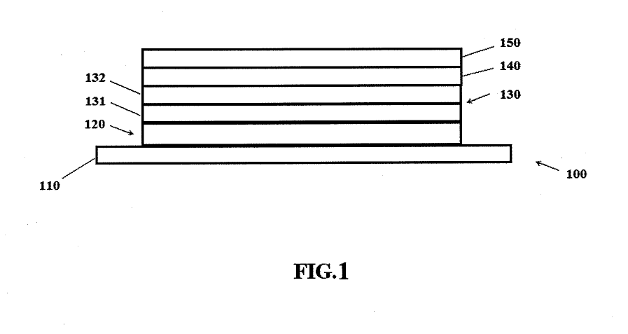

Referring to FIG. 1, photovoltaic device 100 can include transparent conductive oxide layer 120 deposited adjacent to substrate 110. Transparent conductive oxide layer 120 can include a dopant. Transparent conductive oxide layer 120 can be deposited on substrate 110 by reactive sputtering with O₂/Ar gas flow. Transparent conductive oxide layer 120 can be deposited on substrate 110 by sputtering, chemical vapor deposition, or any other suitable deposition method. Substrate 110 can include a glass, such as soda-lime glass. Transparent conductive oxide layer 120 can include cadmium tin oxide (Cd₂SnO₄). Transparent conductive oxide layer 120 can also include cadmium oxide and indium oxide (CdO:(In₂O₃)ₓ). Transparent conductive oxide layer 120 can also include any suitable transparent conductive oxide material, including a cadmium stannate or a tin-doped indium oxide. The thickness of transparent conductive oxide layer 120 can be in the range of about 1000 angstrom to about 2500 angstrom, or any suitable thickness.

A semiconductor bi-layer 130 can be formed or deposited adjacent to transparent conductive oxide layer 120 which can be annealed. Semiconductor bi-layer 130 can include semiconductor window layer 131 and semiconductor absorber layer 132. Semiconductor window layer 131 of semiconductor bi-layer 130 can be deposited adjacent to transparent conductive oxide layer 120. Semiconductor window layer 131 can include any suitable window material, such as cadmium sulfide, and can be deposited by any suitable deposition method, such as sputtering or vapor transport deposition. Semiconductor absorber layer 132 can be deposited adjacent to semiconductor window layer 131. Semiconductor absorber layer 132 can be deposited on semiconductor window layer 131. Semiconductor absorber layer 132 can be any suitable absorber material, such as cadmium telluride, and can be deposited by any suitable method, such as sputtering or vapor transport deposition. Back contact 140 can be deposited adjacent to semiconductor absorber layer 132. Back contact 140 can be deposited adjacent to semiconductor bi-layer 130. Back contact 140 can include any suitable material and can be formed by any suitable method. A back support 150 can be positioned adjacent to back contact 140. Back support 150 can include any suitable material. Back support 150 can include soda-lime glass. A photovoltaic device can have a cadmium sulfide (CdS) layer as a semiconductor window layer and a cadmium telluride (CdTe) layer as a semiconductor absorber layer.

A buffer layer can be deposited between the TCO layer and the semiconductor window layer. The buffer layer can be used to decrease the likelihood of irregularities occurring during the formation of the semiconductor window layer. Additionally, a barrier layer can be incorporated between the substrate and the TCO layer. The barrier layer can include any suitable material. The barrier layer can include a silicon oxide. The barrier layer can include silicon dioxide. The barrier layer can have suitable barrier properties. For example, the barrier layer can form a barrier to sodium. The barrier layer can be deposited by any suitable method. The TCO can be part of a three-layer stack, which may include, for example, a silicon dioxide barrier layer, a cadmium tin oxide TCO layer, and a tin oxide buffer layer. The buffer layer can also include various suitable materials, including zinc tin oxide, zinc oxide, or zinc magnesium oxide.

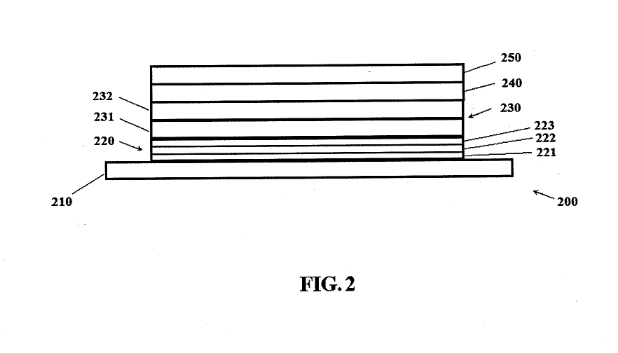

Referring to FIG. 2, photovoltaic device 200 can include TCO stack 220 deposited adjacent to substrate 210. TCO stack 220 can be deposited on substrate 210 by reactive sputtering with O₂/Ar gas flow. Transparent conductive oxide stack 220 can be deposited on substrate 110 by sputtering, chemical vapor deposition, or any other suitable deposition method. Substrate 210 can include a glass, such as soda-lime glass. Transparent conductive oxide stack 220 can include barrier layer 221, transparent conductive oxide layer 222, and buffer layer 223. Barrier layer 221 can be deposited or formed adjacent to substrate 210. Transparent conductive oxide layer 222 can be deposited or formed adjacent to barrier layer 221. Buffer layer 223 can be deposited or formed adjacent to transparent conductive oxide layer. Buffer layer 223 can include any suitable material. Buffer layer 223 can include tin. Buffer layer 223 can include tin oxide. Buffer layer 223 can include silicon. Buffer layer 223 can include a silicon-doped tin oxide layer. The ratio of silicon to tin in buffer layer 223 can be between about 0.1% and 20%, or about 0.5% to about 10%, or about 0.1% to about 2%, or any other suitable ratio.

TCO stack 220 can also be manufactured using a variety of deposition techniques, including for example, low pressure chemical vapor deposition, atmospheric pressure chemical vapor deposition, plasma-enhanced chemical vapor deposition, thermal chemical vapor deposition, DC or AC sputtering, spin-on deposition, and spray-pyrolysis. Each deposition layer can be of any suitable thickness in the range of about 1 to about 5000 angstrom. For example, the thicknesses of barrier layer 221, transparent conductive oxide layer 222, and buffer layer 223 can be in the range of about 1000 angstrom to about 2500 angstrom respectively. Bather layer 221 can include silicon oxide. Transparent conductive oxide layer 222 can include cadmium tin oxide (Cd₂SnO₄). Buffer layer 223 can include tin oxide. Transparent conductive oxide layer 222 can also include any suitable transparent conductive oxide material, including a cadmium stannate or a tin-doped indium oxide. TCO stack 220 can transform to conducting/transparent state during the following semiconductor layers deposition process, thus no additional annealing process is needed.

Semiconductor bi-layer 230 can be formed or deposited adjacent to transparent conductive oxide stack 220. Semiconductor bi-layer 230 can include semiconductor window layer 231 and semiconductor absorber layer 232. Semiconductor window layer 231 of semiconductor bi-layer 230 can be deposited adjacent to transparent conductive oxide stack 220. Semiconductor window layer 231 can include any suitable window material, such as cadmium sulfide, and can be deposited by any suitable deposition method, such as sputtering or vapor transport deposition. Semiconductor absorber layer 232 can be deposited adjacent to semiconductor window layer 231. Semiconductor absorber layer 232 can be deposited on semiconductor window layer 231. Semiconductor absorber layer 232 can be any suitable absorber material, such as cadmium telluride, and can be deposited by any suitable method, such as sputtering or vapor transport deposition. Back contact 240 can be deposited adjacent to semiconductor absorber layer 232. Back contact 240 can be deposited adjacent to semiconductor bi-layer 230. A back support 250 can be positioned adjacent to back contact 240.

Silicon-doped tin oxide buffer layer 223 can be reactively sputter deposited from a sputter target. The sputter target can include a rotary sputter target. The sputter target can include a doped sputter target. The sputter target can include tin. The sputter target can include silicon. The sputter target can include tin and silicon. The sputter target can have a silicon weight percentage ranging from about 0.1% to about 20%, or about 0.5% to about 10%, or about 0.1% to about 2%, or any other suitable weight percentage. The sputter target can have a silicon weight percentage of about 1% silicon. The sputtering can occur in a sputter chamber. The sputter chamber can include oxygen.

The doped rotary sputter targets including a sputter material having tin and silicon can be made by any suitable sputter target manufacture process. The tin and silicon sputter target can be made by spray forming processes (thermal or plasma), or powder metallurgy (hot pressed or isostatic pressed), or by other suitable techniques. The targets can include a sputtering material in connection with a backing material. The sputter material can include tin. The sputter material can include silicon. The sputter material can include tin and silicon. The sputter material can have a silicon weight percentage ranging from about 0.1% to about 20%, or about 0.5% to about 10%, or about 0.1% to about 2%, or any other suitable weight percentage. The sputter material can have a silicon weight percentage of about 1% silicon. The backing material can include stainless steel. The backing material can include a backing tube. The backing material can include a stainless steel backing tube. The sputter target can include bonding layers applied to the tube surface before application of the Si:Sn sputter material.

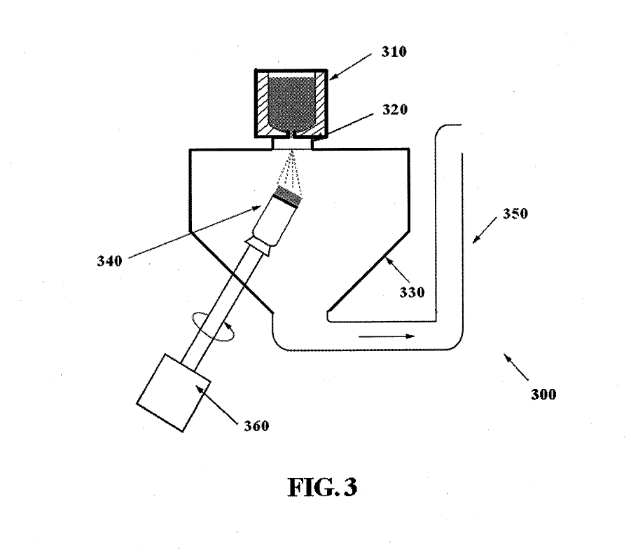

The doped rotary sputter target can be manufactured by spraying a target material onto a base. Metallic target material can be sprayed by any suitable spraying process, including thermal spraying and plasma spraying. The metallic target material can include multiple metals, present in stoichiometrically proper amounts. The base onto which the metallic target material is sprayed can be a tube. Referring to FIG. 3, thermal spray forming process is a method of casting near net shape metal components with homogeneous microstructures via the deposition of semi-solid sprayed droplets onto a shaped substrate. In spray forming system 300, an alloy can be melted in induction furnace 310, then the molten metal with dopant can be slowly poured through a conical tundish into small-bore ceramic nozzle 320. The molten metal exits the furnace as a thin free-falling stream and is broken up into droplets by an annular array of gas jets, and these droplets then proceed downwards into chamber 330, accelerated by the gas jets to impact onto rotary substrate 340. The process can be arranged such that the droplets strike rotary substrate 340 in the semi-solid condition, this can provide sufficient liquid fraction to ‘stick’ the solid fraction together. Deposition continues, gradually building up a spray formed billet of metal on rotary substrate 340. Spray forming system 300 can further include outlet 350 to exhaust gas. Rotary substrate 340 can be driven by driven unit 360. The resulted pre-form can be porous. In a following step, the pre-from can be consolidated further by Hot Isostatic Pressing (HIP) to 100% density. Spray forming process can have the potential economic benefit to be gained from reducing the number of process steps between melt and finished product. Spray forming can be used to produce strip, tube, ring, clad bar/roll and cylindrical extrusion feed stock products, in each case with a relatively fine-scale microstructure even in large cross-sections. The doped sputter target can have a tin, silicon composition. The doped sputter target can have a silicon weight percentage ranging from about 0.1% to about 20%, 0.5% to about 10%, or about 0.1% to about 2%, or any other suitable weight percentage. Sputter material deposited on rotary, substrate 340 can have a silicon weight percentage ranging from about 0.1% to about 20%, 0.5% to about 10%, or about 0.1% to about 2%, or any other suitable weight percentage.

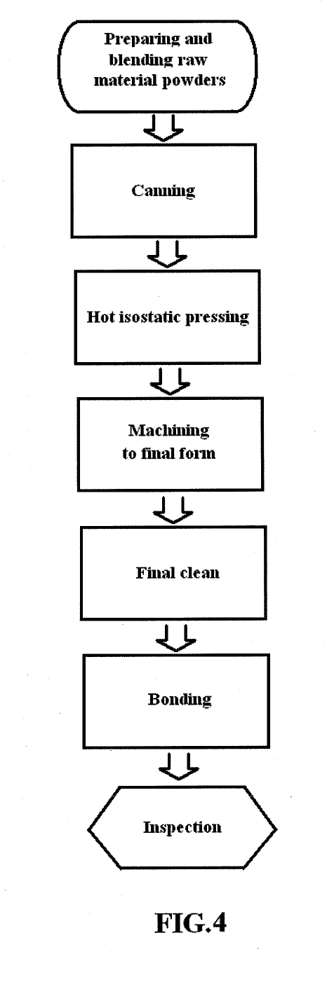

A sputter target can also be manufactured by powder metallurgy. A sputter target can be formed by consolidating metallic powder to form the target. The metallic powder can be consolidated in any suitable process (e.g., pressing such as isostatic pressing) and in any suitable shape. The consolidating can occur at any suitable temperature. A sputter target can be formed from metallic powder including more than one metal powder. More than one metallic powder can be present in stoichiometrically proper amounts. Referring to FIG. 4, the process of making a doped sputter target can include the steps of preparing and blending raw material oxide powders, canning the powders, hot isostatic pressing the powders, machining to final form, final clean, bonding, and inspection. Making a doped sputter target can further include annealing or any other suitable metallurgy technique or other treatment. Powders can include metal powders, such as tin, and dopant powders, such as silicon. The doped sputter target can have a silicon weight percentage ranging from about 0.1% to about 20%, 0.5% to about 10%, or about 0.1% to about 2%, or any other suitable weight percentage. In other embodiments, the doped sputter target can also include other suitable dopant. In certain embodiments, the process of making a doped sputter target can further include a pre treatment or post treatment for bonding layers.

A sputter target can also be manufactured by ingot metallurgy. A sputter target can include one or more components of a layer or film to be deposited or otherwise formed on a surface, such as a substrate. For example, a sputter target can include one or more components of an oxide buffer layer to be deposited on top of TCO layers, such as tin for a tin oxide buffer layer or a dopant such as silicon. The components can be present in the target in stoichiometrically proper amounts. A sputter target can be manufactured as a single piece in any suitable shape. A sputter target can be a tube. A sputter target can be manufactured by casting a metallic material into any suitable shape, such as a tube. A sputter target can also be manufactured from more than one piece. A sputter target can be manufactured from more than one piece of metal, for example, a piece of tin for a tin oxide buffer layer and a piece of dopant material, such as silicon. The components can be formed in any suitable shape, such as sleeves, and can be joined or connected in any suitable manner or configuration. One sleeve can be positioned within another sleeve. In certain embodiments, a sputter target can also be manufactured by positioning wire including target material adjacent to a base. For example wire including target material can be wrapped around a base tube. The wire can include multiple metals present in stoichiometrically proper amounts. The base tube can be formed from a material that will not be sputtered. The wire can be pressed (e.g., by isostatic pressing).

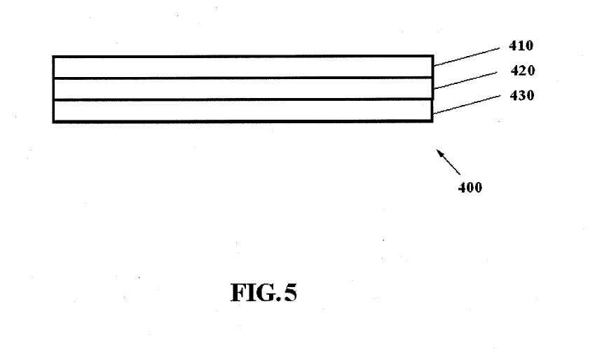

Referring to FIG. 5, silicon doped rotary target 400 can include stainless steel backing tube 430, bonding layer 420, and Si:Sn sputter target material 410. Bonding layer 420 can be applied to tube 430 surface before application of Si:Sn sputter target material 410. Bonding layer 420 can enable a high quality, high melting temperature solder bond between Si:Sn sputter target material 410 and backing tube 430. In certain embodiments, bonding layer 420 can allow the user to increase sputtering rates by 30-100%. Bonding layer 420 can produce a strong, flat, low stress bond that is highly thermally and electrically conductive.

Bonding layer 420 can also include layers of low vapor pressure metals which can be applied to both backing tube 430 and target material 410. Backing tube 430 and target material 410 can then be diffusion bonded together. This bond can provide the necessary mechanical strength required to hold the two materials together. This bond can also provide a high thermally and electrically conductive layer for transfer of heat and electricity from backing tube 430 to target material 410. In addition, the bond can provide a differential slip plane to allow for differences in thermal expansion between the target and the backing plate. This prevents the target from debonding or cracking during the heat up and cool down cycle of the plasma deposition process. A sputter target including silicon and tin sputter material can also be mounted on any suitable backing member (e.g., backing plate). Si:Sn sputter target material can also be mounted on the backing member by any suitable connector (e.g., a screw, bolt, weld, or adhesive).

Doped rotary target 400 can include tin and silicon. Doped rotary target 400 can be made from a thermal spray forming, plasma spray forming, powder metallurgy, or flow forming process. The powder metallurgy can include hot press process or isostatic process. Doped rotary target 400 can have a silicon weight percentage ranging from about 0.1% to about 20%, or about 0.5% to about 10%, or about 0.1% to about 2%, or any other suitable percentage. Doped rotary target 400 can be configured to use in reactive sputtering process.

The oxide buffer layer can be deposited by sputtering. In a sputter process, argon plasma can be formed between a substrate and target material and atoms constituting the target material are sputtered out by energetic argon atoms impacting against the sputter target. The sputtered atoms can be deposited on the substrate, forming a thin film on the substrate's surface.

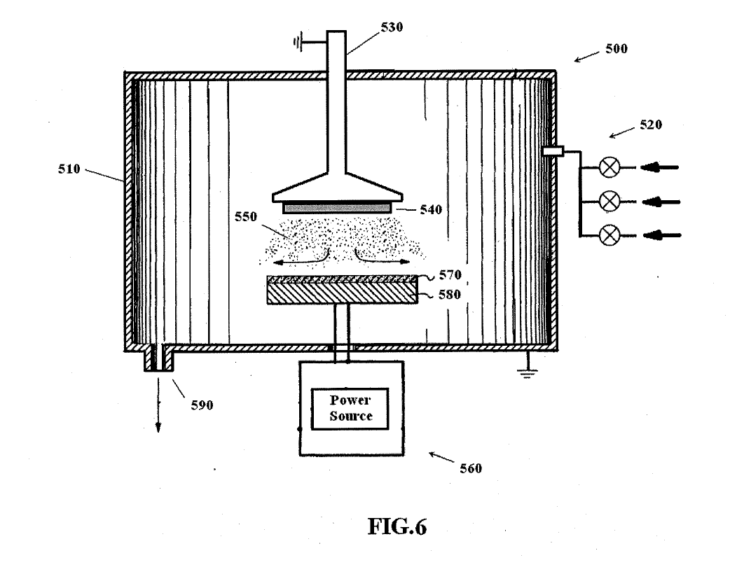

Referring to FIG. 6, sputter system 500 can include chamber 510. Sputter system 500 can be a DC sputtering system and include pulsed DC power supply 560 with a 4 microsecond pulse. The power output of the source can range from about 3 kW (˜1.4 W/cm²) to about 9 kW (˜4.2 W/cm²). The target voltage can range from about 300 volts to about 420 volts. Sputter system 500 can also be a RF sputtering system and include radio-frequency source and matching circuit. Substrate 570 can be mounted on plate 580 or positioned in any other suitable manner. The target-to-substrate distance can range from 50 mm to 500 mm. Grounded rotary fixture 530 can hold doped sputter target 540 facing down. The gas in chamber 510 is taken from inlet 520 with sources of different gas. The gas in chamber 510 can include argon and oxygen. The pressure in chamber 510 can be within the range from about 2.0 mTorr to about 8.0 mTorr. During sputtering process, particles 550 can be deposited from target 540 to substrate 570.

The sputtering process can be a reactive sputtering process. The deposited oxide buffer layer can be formed by chemical reaction between the target material and the gas which is introduced into the vacuum chamber. The composition of the film can be controlled by varying the relative pressures or gas flow rates of the inert and reactive gases in chamber 510. For example, the inert gas can be argon and the reactive gas can be oxygen. In other embodiments, the gas in chamber 510 can further include other dopant gas. System 500 can include outlet 590 to exhaust gas. In other embodiments, the sputtering process can be a magnetron sputter deposition, or ion assisted deposition.

The transparent conductive oxide layer can also be doped with a dopant, such as titanium, gallium, tin, yttrium, scandium, niobium, or molybdenum. The transparent conductive oxide layer can also be doped with a dopant to manage its band gap, such as magnesium cadmium oxide (MgₓCd_{y}O_{z}:In) or zinc cadmium oxide (ZnₓCd_{y}O_{z}:In).

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A photovoltaic device comprising:
a substrate;
a barrier layer adjacent to the substrate;
a transparent conductive oxide layer adjacent to the barrier layer; and
a buffer layer adjacent to the transparent conductive oxide layer, wherein the buffer layer comprises silicon-doped tin oxide.

2. The photovoltaic device of claim 1, wherein the weight percentage of silicon to tin in the buffer layer is between about 0.1% and about 20%.

3. The photovoltaic device of claim 2, wherein the weight percentage of silicon to tin in the buffer layer is between about 0.5% and about 10%.

4. The photovoltaic device of claim 2, wherein the weight percentage of silicon to tin in the buffer layer is between about 0.1% and about 2%.

5. The photovoltaic device of claim 1, wherein the transparent conductive oxide layer comprises cadmium oxide.

6. The photovoltaic device of claim 1, wherein the transparent conductive oxide layer comprises cadmium tin oxide.

7. The photovoltaic device of claim 1, wherein the substrate comprises glass.

8. The photovoltaic device of claim 1, further comprising a semiconductor bi-layer adjacent to the transparent conductive oxide layer, wherein the semiconductor bi-layer comprises a semiconductor absorber layer and a semiconductor window layer.

9. The photovoltaic device of claim 8, wherein the semiconductor absorber layer comprises cadmium telluride.

10. The photovoltaic device of claim 8, wherein the semiconductor window layer comprises cadmium sulfide.

11. The photovoltaic device of claim 1, wherein the barrier layer comprises silicon oxide.

12. The photovoltaic device of claim 1, wherein the thicknesses of the buffer layer is between about 500 angstrom and about 5000 angstrom.

13. The photovoltaic device of claim 12, wherein the thicknesses of the buffer layer is between about 1000 angstrom and about 2500 angstrom.

14. A method of manufacturing a photovoltaic device comprising the steps of:
depositing a barrier layer adjacent to a substrate;
depositing a transparent conductive oxide layer adjacent to the barrier layer; and
depositing a buffer layer adjacent to the transparent conductive oxide layer, wherein the buffer layer comprises silicon-doped tin oxide.

15. The method of claim 14, further comprising depositing a semiconductor bi-layer adjacent to the buffer layer, wherein the semiconductor bi-layer comprises a semiconductor absorber layer and a semiconductor window layer.

16. The method of claim 14, wherein depositing the buffer layer comprises sputtering a sputter target.

17. The method of claim 16, wherein the sputtering comprises reactive sputtering.

18. The method of claim 16, wherein the sputter target comprises tin and silicon.

19. The method of claim 18, wherein the sputter target has a silicon weight percentage ranging from about 0.1% to about 20%.

20. The method of claim 18, wherein the sputter target has a silicon weight percentage ranging from about 0.5% to about 10%.

21. The method of claim 18, wherein the sputter target has a silicon weight percentage ranging from about 0.1% to about 2%.

22. The method of claim 16, wherein the sputtering comprises reactive sputtering from a rotary target comprising tin and silicon, wherein the sputtering occurs in the presence of oxygen in a sputter chamber.

23. The method of claim 14, wherein depositing the transparent conductive oxide layer comprises reactive sputtering from a doped target.

24. The method of claim 14, further comprising an annealing step to anneal the transparent conductive oxide.

25. A sputter target comprising:
a sputter material containing silicon and tin; and
a backing tube, wherein the sputter material is connected to the backing tube to form a sputter target.

26. The sputter target of claim 25 comprising a silicon weight percentage of about 0.1% to about 20%.

27. The sputter target of claim 26 comprising a silicon weight percentage of about 0.5% to about 10%.

28. The sputter target of claim 26 comprising a silicon weight percentage of about 0.1% to about 2%.

29. The sputter target of claim 25, further comprising a bonding layer bonding the sputter material and the backing tube.

30. The sputter target of claim 25, wherein the backing tube comprises stainless steel.

31. The sputter target of claim 25, wherein the sputter target is configured to use in reactive sputtering process.

32. A method of manufacturing a rotary sputter target configured for use in manufacture of photovoltaic device comprising the steps of:
forming a sputter material comprising tin and silicon; and
attaching the sputter material to a backing tube to form a sputter target.

33. The method of claim 32, wherein the step of attaching the sputter material to a backing tube to form a sputter target comprises a thermal spray forming process.

34. The method of claim 32, wherein the step of attaching the sputter material to a backing tube to form a sputter target comprises a plasma spray forming process.

35. The method of claim 32, wherein the step of attaching the sputter material to a backing tube to form a sputter target comprises a powder metallurgy process.

36. The method of claim 35, wherein the powder metallurgy comprises hot press process.

37. The method of claim 35, wherein the powder metallurgy comprises isostatic process.

38. The method of claim 32, wherein the step of attaching the sputter material to a backing tube to form a sputter target comprises a flow forming process.

39. The method of claim 32, wherein the sputter material has a silicon weight percentage ranging from about 0.1% to about 20%.

40. The method of claim 39, wherein the sputter material has a silicon weight percentage ranging from about 0.5% to about 10%.

41. The method of claim 39, wherein the sputter material has a silicon weight percentage ranging from about 0.1% to about 2%.

42. The method of claim 32, wherein the step of attaching the sputter material to the backing tube comprises bonding the sputtering material to the backing tube with a bonding layer.

43. The method of claim 32, wherein the backing tube comprises stainless steel.

44. The method of claim 32, wherein the sputter target is configured to use in reactive sputtering process.
